(19) United States
(12) Patent Application Publication
(10) Pub. No.: US 2025/0287586 A1
(43) Pub. Date: Sep. 11, 2025

(54) SEMICONDUCTOR DEVICE AND METHOD OF MANUFACTURING THE SAME

(71) Applicant: SK hynix Inc., Icheon-si Gyeonggi-do (KR)

(72) Inventor: Jae Ho KIM, Icheon-si Gyeonggi-do (KR)

(73) Assignee: SK hynix Inc., Icheon-si Gyeonggi-do (KR)

(21) Appl. No.: 18/775,228

(22) Filed: Jul. 17, 2024

(30) Foreign Application Priority Data
Mar. 8, 2024 (KR) 10-2024-0032947

(51) Int. Cl. H10B 43/20; H10B 41/10; H10B 41/20; H10B 43/10; H10B 99/00

(52) U.S. Cl. CPC H10B 43/20; H10B 41/10; H10B 41/20; H10B 43/10; H10B 99/16

(57) ABSTRACT

A semiconductor device, and a method of manufacturing the semiconductor device, includes a transistor including a gate insulating layer and a gate electrode stacked on a substrate. The semiconductor device also includes a diode including a diode electrode, wherein the diode electrode is on the substrate, extends from the gate electrode, and is electrically connected to the gate electrode. The semiconductor device further includes a first plug physically and electrically connected to the diode electrode.

### CROSS-REFERENCE TO RELATED APPLICATION

The present application claims priority under 35 U.S.C. § 119(a) to Korean patent application number 10-2024-0032947 filed on Mar. 8, 2024, in the Korean Intellectual Property Office, the entire contents of which application is incorporated herein by reference.

### BACKGROUND

### 1. Technical Field

Various embodiments of the present disclosure generally relate to a semiconductor device and a method of manufacturing the semiconductor device, and more particularly, to a semiconductor device including a transistor and a diode and a method of manufacturing the semiconductor device.

### 2. Related Art

As an electronic device using a semiconductor memory device is miniaturized, there is a need to reduce the area of the semiconductor memory device. To satisfy this need, a peripheral under cell (PUC) structure in which a peripheral circuit structure controlling the operation of memory cells is disposed under the memory cells has been proposed.

### SUMMARY

A semiconductor device according to an embodiment of the present disclosure may include a transistor including a gate insulating layer and a gate electrode stacked on a substrate. The semiconductor device may also include a diode including a diode electrode, wherein the diode electrode is on the substrate, extends from the gate electrode, and is electrically connected to the gate electrode. The semiconductor device may further include a first plug physically and electrically connected to the gate electrode.

A method of manufacturing a semiconductor device according to an embodiment of the present disclosure may include forming a transistor including a gate insulating layer and a gate electrode stacked on a substrate. The method may also include forming a diode including a diode electrode, the diode electrode formed on the substrate and extending from the gate electrode. The method may further include forming a first plug that is physically connected to the diode electrode and electrically connected to both the gate electrode and the diode electrode, wherein the first plug is formed to not overlap the transistor.

### BRIEF DESCRIPTION OF THE DRAWINGS

FIG. 1 is a diagram illustrating a semiconductor device according to an embodiment of the present disclosure.

FIG. 2 is a diagram illustrating a semiconductor device according to an embodiment of the present disclosure.

FIGS. 3A to 3E are diagrams illustrating a configuration of a peripheral circuit structure according to an embodiment of the present disclosure.

FIGS. 4A to 4H are diagrams illustrating a method of manufacturing a peripheral circuit structure according to an embodiment of the present disclosure.

FIGS. 5A to 5H are diagrams illustrating configurations of a peripheral circuit structure according to other embodiments of the present disclosure.

FIG. 6 is a diagram illustrating a memory card system to which a semiconductor device according to an embodiment of the present disclosure is applied.

FIG. 7 is a diagram illustrating a solid-state drive (SSD) system to which a semiconductor device according to the present disclosure is applied.

### DETAILED DESCRIPTION

Specific structural or functional descriptions for embodiments of the present disclosure introduced in this specification or application are provided as examples to describe embodiments according to the concept of the present disclosure. Embodiments according to the concept of the present disclosure may be practiced in various forms, and should not be construed as being limited to the specific embodiments described in the specification or application.

Hereinafter, various embodiments of the present disclosure are described in detail with reference to the accompanying drawings in which embodiments of the present disclosure are shown so that those skilled in the art to which the present disclosure pertains can practice the technical spirit of the present disclosure.

Some embodiments of the present disclosure are directed to a semiconductor device, and a method of manufacturing the semiconductor device, which can reduce damage to a peripheral circuit structure and reduce the size of the peripheral circuit structure.

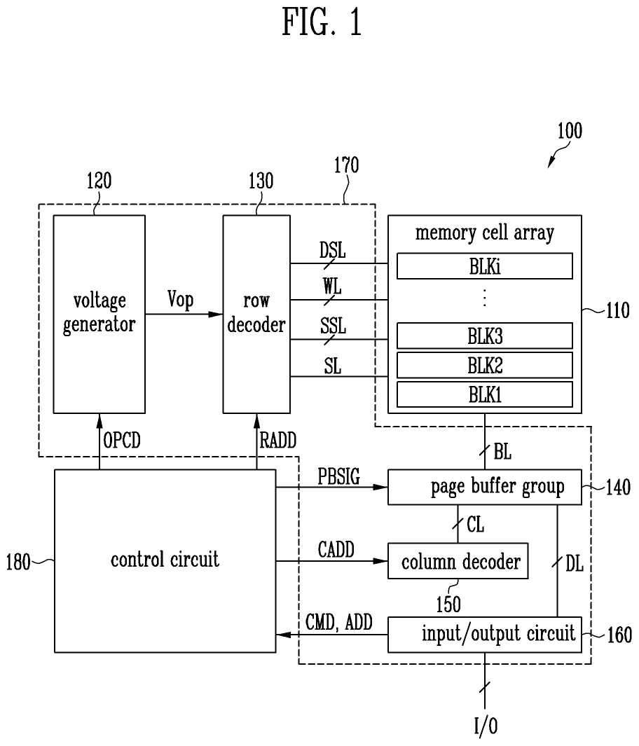

FIG. 1 is a diagram illustrating a semiconductor device according to an embodiment of the present disclosure.

Referring to FIG. 1, a semiconductor device 100 may include a memory cell array 110, a peripheral circuit 170, and a control circuit 180. In the present disclosure, the semiconductor device 100 may be a memory device.

The memory cell array 110 may include first to i-th memory blocks BLK1 to BLKi. Each of the first to i-th memory blocks BLK1 to BLKi may include memory cells capable of storing data. Drain select lines DSL, word lines WL, source select lines SSL, and a source line SL may be coupled to each of the first to i-th memory blocks BLK1 to BLKi, and bit lines BL may be coupled in common to the first to i-th memory blocks BLK1 to BLKi.

Each of the first to i-th memory blocks BLK1 to BLKi may be formed to have a two-dimensional (2D) structure or a three-dimensional (3D) structure. Each memory block having a 2D structure may include memory cells arranged in parallel on a substrate. Each memory block having a 3D structure may include memory cells stacked on a substrate in a vertical direction. Although memory blocks formed to have a 3D structure are described for convenience of description, the present teachings may also be applied to memory blocks having a 2D structure.

According to a program scheme, each memory cell may store 1 bit of data or 2 or more bits of data. For example, a scheme for storing 1 bit of data in one memory cell is referred to as a single-level cell (SLC) scheme, and a scheme for storing 2 bits of data in one memory cell is referred to as a multi-level cell (MLC) scheme. A scheme for storing 3 bits of data in one memory cell is referred to as a triple-level cell (TLC) scheme, and a scheme for storing 4 bits of data in one memory cell is referred to as a quad-level cell (QLC) scheme. In addition, 5 or more bits of data may be stored in one memory cell.

The peripheral circuit 170 may perform a program operation of storing data in the memory cell array 110, a read operation of outputting data stored in the memory cell array 110, and an erase operation of erasing data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop that are used for a program operation, a read operation, or an erase operation in response to an operation code OPCD. For example, the voltage generator 120 may generate program voltages, turn-on voltages, turn-off voltages, negative voltages, precharge voltages, verify voltages, read voltages, pass voltages, or erase voltages in response to the operation code OPCD. The operating voltages Vop generated by the voltage generator 120 may be applied to the drain select lines DSL, the word lines WL, the source select lines SSL, and the source line SL of a memory block selected through the row decoder 130.

The program voltages may be voltages that are applied to a selected word line among the word lines WL during a program operation, and may be used to increase the threshold voltages of memory cells coupled to the selected word line. The turn-on voltages may be applied to the drain select lines DSL or the source select lines SSL, and may be used to turn on drain select transistors or source select transistors. The turn-off voltages may be applied to the drain select lines DSL or the source select lines SSL, and may be used to turn off the drain select transistors or source select transistors. For example, the turn-off voltage may be set to 0 V. The precharge voltages may be voltages higher than 0 V, and may be applied to the bit lines during a read operation. The verify voltages may be used for a verify operation of determining whether the threshold voltages of selected memory cells have increased to a target level. The verify voltages may be set to various levels according to the target level, and may be applied to a selected word line.

The read voltages may be applied to the selected word line during a read operation performed on the selected memory cells. For example, the read voltages may be set to various levels according to the program scheme for the selected memory cells. The pass voltages may be voltages that are applied to unselected word lines among the word lines WL during a program or read operation, and may be used to turn on memory cells coupled to the unselected word lines. The erase voltages may be used during an erase operation of erasing the memory cells included in the selected memory block, and may be applied to the source line SL.

The row decoder 130 may transfer the operating voltages Vop to the drain select lines DSL, the word lines WL, the source select lines SSL, and the source line SL, which are coupled to a memory block selected according to the row address RADD. For example, the row decoder 130 may be coupled to the voltage generator 120 through global lines, and may be coupled to the first to i-th memory blocks BLK1 to BLKi through the drain select lines DSL, the word lines WL, the source select lines SSL, and the source line SL.

The page buffer group 140 may include page buffers (not illustrated) coupled to the first to i-th memory blocks BLK1 to BLKi, respectively. The page buffers may be coupled to the first to i-th memory blocks BLK1 to BLKi through the bit lines BL. During a read operation the page buffers may sense the currents or voltages of bit lines varying with the threshold voltages of the selected memory cells in response to page buffer control signals PBSIG, and may temporarily store the sensed data.

The column decoder 150 may be configured such that data is transferred between the page buffer group 140 and the input/output circuit 160 in response to a column address CADD. For example, the column decoder 150 may be coupled to the page buffer group 140 through column lines CL, and may transmit enable signals through the column lines CL. The page buffers (not illustrated) included in the page buffer group 140 may receive or output data through data lines DL in response to the enable signals.

The input/output circuit 160 may receive or output a command CMD, an address ADD, or data through input/output lines I/O. For example, the input/output circuit 160 may transmit the command CMD and the address ADD, received from an external controller through the input/output lines I/O, to the control circuit 180, and may transmit the data, received from the external controller through the input/output lines I/O, through the data lines DL to the page buffer group 140. Alternatively, the input/output circuit 160 may output data, received from the page buffer group 140, to the external controller through the input/output lines I/O.

The control circuit 180 may output at least one of the operation code OPCD, the row address RADD, the page buffer control signals PBSIG, or the column address CADD in response to the command CMD and the address ADD. For example, when the command CMD input to the control circuit 180 is a command corresponding to a program operation, the control circuit 180 may control the peripheral circuit 170 so that a program operation is performed on a memory block selected by the address ADD. When the command CMD input to the control circuit 180 is a command corresponding to a read operation, the control circuit 180 may control the peripheral circuit 170 so that a read operation is performed on a memory block selected by the address and read data is output. When the command CMD input to the control circuit 180 is a command corresponding to an erase operation, the control circuit 180 may control the peripheral circuit 170 so that an erase operation is performed on a selected memory block.

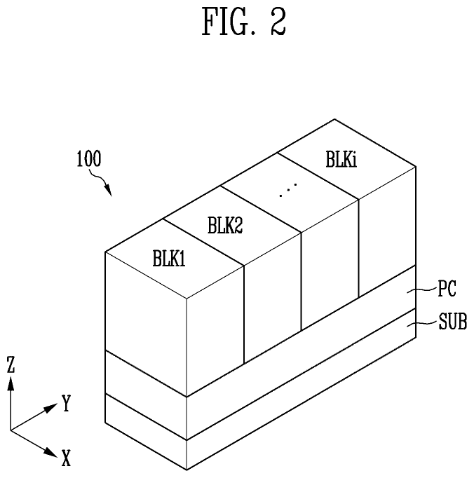

FIG. 2 is a diagram schematically illustrating a semiconductor device according to an embodiment of the present disclosure.

Referring to FIG. 2, the semiconductor device 100 (e.g., memory device) may include a peripheral circuit structure PC disposed on a substrate SUB and memory blocks BLK1 to BLKi. The memory blocks BLK1 to BLKi may overlap the peripheral circuit structure PC.

The substrate SUB may be a single crystal semiconductor layer. For example, the substrate SUB may be a bulk silicon substrate, a silicon-on-insulator substrate, a germanium substrate, a germanium-on-insulator substrate, a silicon-germanium substrate, or an epitaxial thin film formed through a selective epitaxial growth method.

The peripheral circuit structure PC may include a row decoder 130, a column decoder 150, a page buffer group 140, a control circuit 180, etc., which constitute a circuit for controlling the operation of the memory blocks BLK1 to BLKi. For example, the peripheral circuit structure PC may include a transistor (e.g., an NMOS transistor or a PMOS transistor), a diode (e.g., a PN diode), a resistor, a capacitor, etc., which are electrically connected to the memory blocks BLK1 to BLKi. The peripheral circuit structure PC may be disposed under the memory blocks BLK1 to BLKi. The peripheral circuit structure PC may be disposed on the substrate SUB. Unlike the configuration illustrated in FIG. 2, the peripheral circuit structure PC may include a portion of the substrate SUB. For example, a portion of the transistor (or a portion of the diode) included in the peripheral circuit structure PC may be formed in the substrate SUB.

Each of the memory blocks BLK1 to BLKi may include a source structure, bit lines, cell strings electrically connected to the source structure and the bit lines, word lines electrically connected to the cell strings, and select lines electrically connected to the cell strings. Each of the cell strings may include memory cells and select transistors which are connected in series by a cell plug. Each of the select lines may be used as a gate electrode of a select transistor corresponding thereto, and each of the word lines may be used as a gate electrode of a memory cell corresponding thereto.

In an embodiment, unlike the configuration illustrated in FIG. 2, the peripheral circuit structure PC may be disposed in partial areas of the substrate SUB that do not overlap the memory blocks BLK1 to BLKi. For example, the peripheral circuit structure PC and the memory blocks BLK1 to BLKi may be disposed in respective areas that do not overlap each other on the substrate SUB.

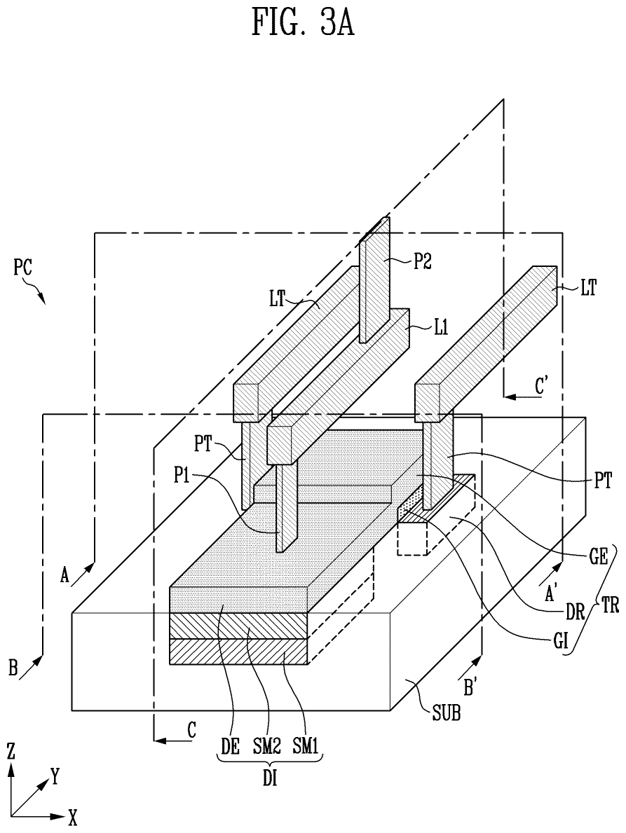

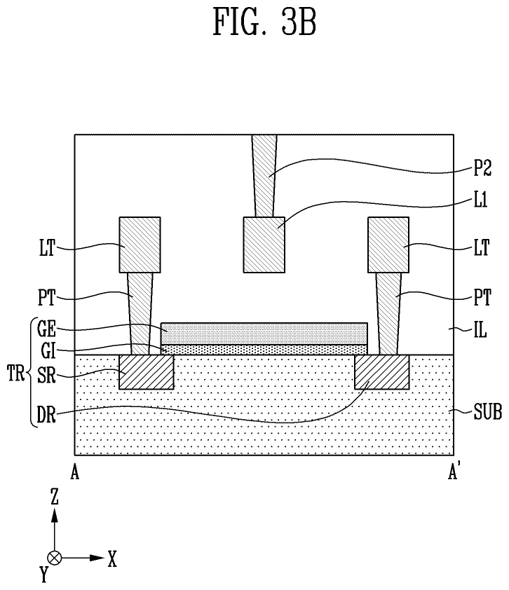

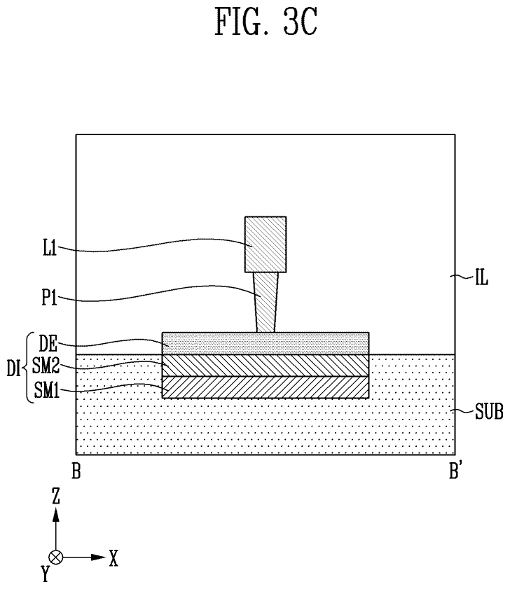

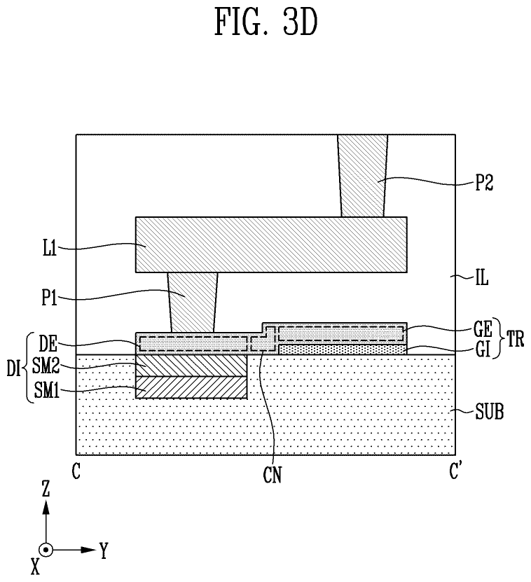

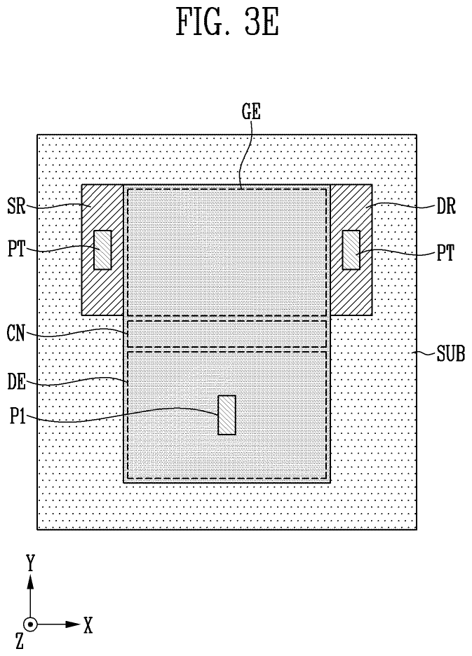

FIGS. 3A to 3E are diagrams illustrating a configuration of a peripheral circuit structure according to an embodiment of the present disclosure.

FIG. 3A illustrates a portion of the peripheral circuit structure PC included in the semiconductor device (e.g., the semiconductor device 100 of FIGS. 1 and 2) according to the present disclosure. It may be understood that a portion of the peripheral circuit structure PC described in FIG. 2 is shown in FIG. 3A. Although the memory cell array (e.g., the memory cell array 110 of FIG. 1) is not shown in FIG. 3A, it may be understood that the memory cell array is disposed over the peripheral circuit structure PC of FIG. 3A.

FIG. 3B is a sectional view taken along line A-A′ of FIG. 3A. FIG. 3C is a sectional view taken along line B-B′ of FIG. 3A. FIG. 3D is a sectional view taken along line C-C′ of FIG. 3A. FIG. 3E is a plan view showing a layout of FIG. 3A.

Referring to FIGS. 3A and 3B, the transistor TR may include a gate insulating layer GI and a gate electrode GE stacked on a substrate SUB. The gate electrode GE may be located on the gate insulating layer GI. The gate insulating layer GI may include an insulating material (e.g., oxide layer). The gate electrode GE may include a conductive material (e.g., metal). Further, the transistor TR may include a source region SR and a drain region DR formed in the substrate SUB. The source region SR may be disposed adjacent to one side (e.g., in a direction opposite to the X direction) of the gate electrode GE, and the drain region DR may be disposed adjacent to the other side (e.g., in the X direction) of the gate electrode GE. A portion of the source region SR and a portion of the drain region DR might or might not overlap a portion of the gate electrode GE. The source region SR and the drain region DR may contain a first type (e.g., N type) of impurities. Alternatively, the source region SR and the drain region DR may contain a second type (e.g., P type) of impurities.

Referring to FIGS. 3A and 3C, a diode DI may include a first semiconductor region SM1 and a second semiconductor region SM2. The second semiconductor region SM2 may be located on the first semiconductor region SM1. The first semiconductor region SM1 may contain the first type (e.g., N type) of impurities, and the second semiconductor region SM2 may contain the second type (e.g., P type) of impurities. The diode DI may include a diode electrode DE stacked on the substrate SUB. The diode electrode DE may be located on the second semiconductor region SM2. The diode electrode DE may contact the second semiconductor region SM2. The diode electrode DE may overlap the first and second semiconductor regions SM1 and SM2. The diode electrode DE may include a conductive material (e.g., metal).

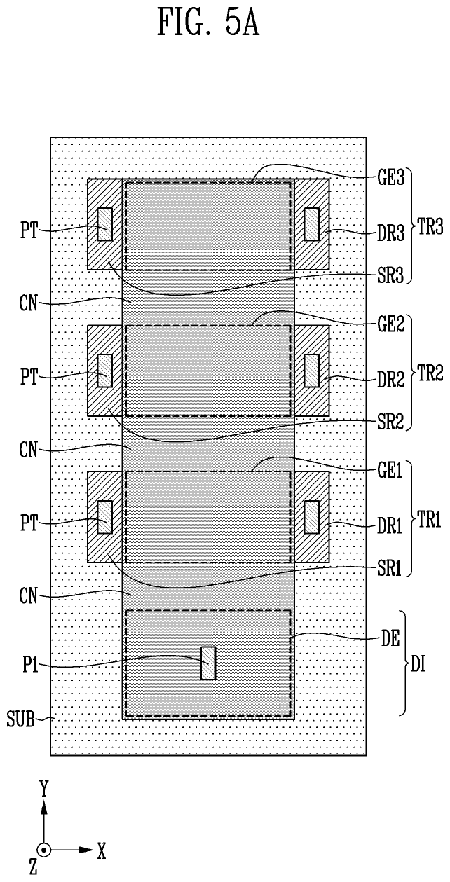

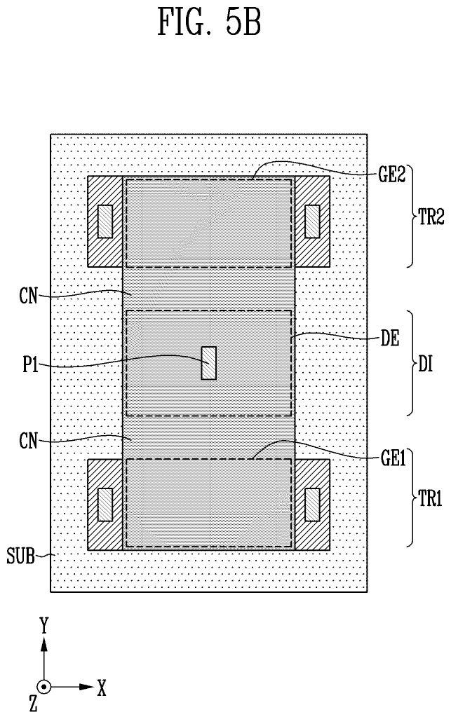

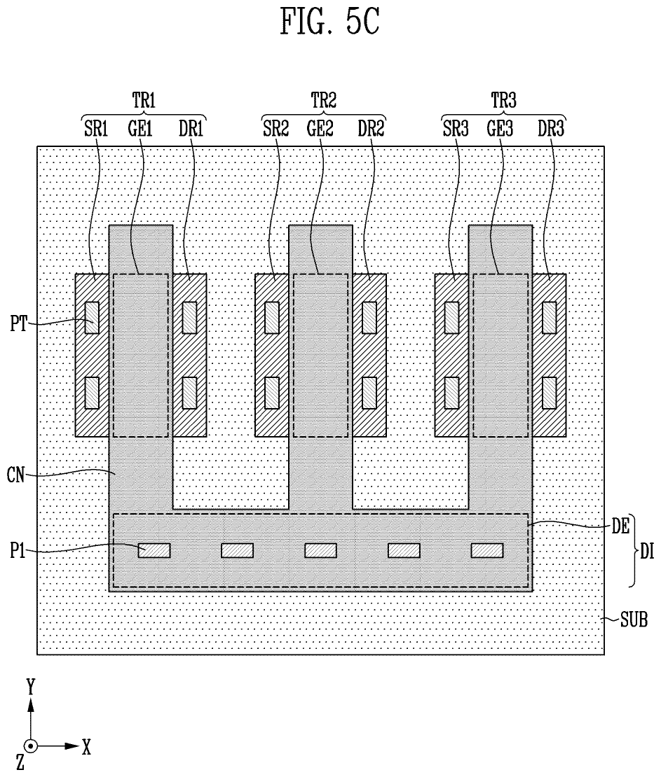

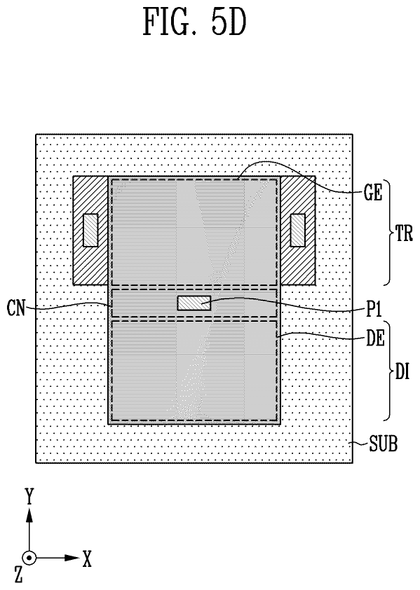

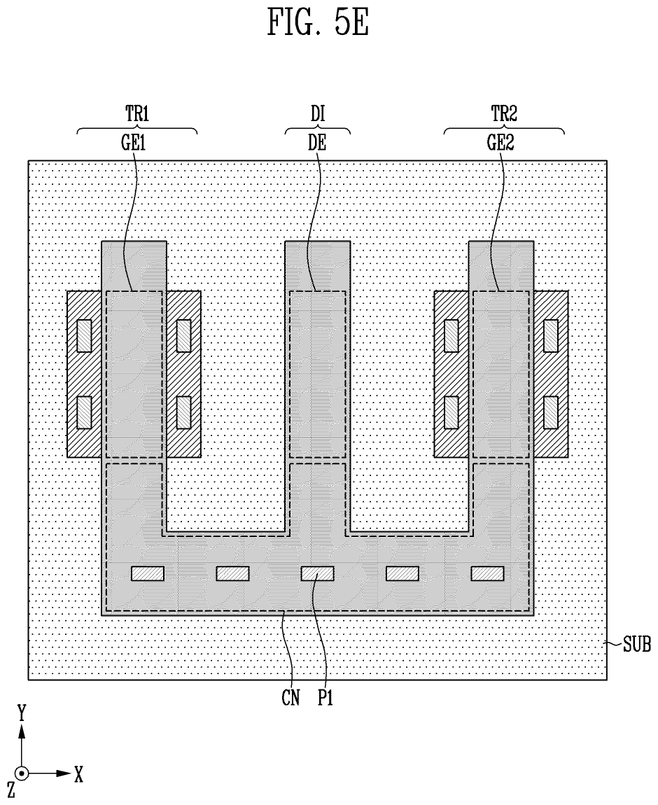

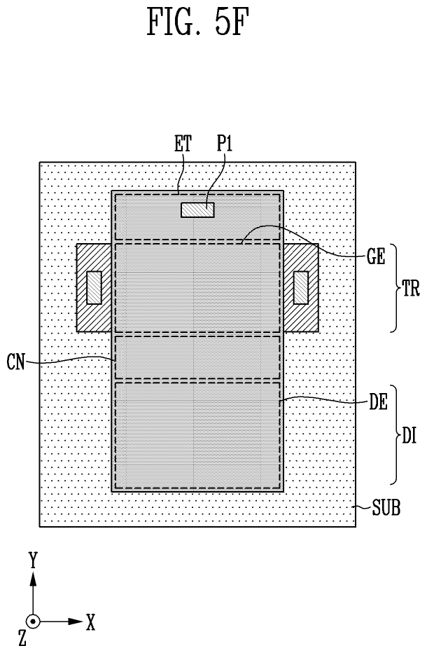

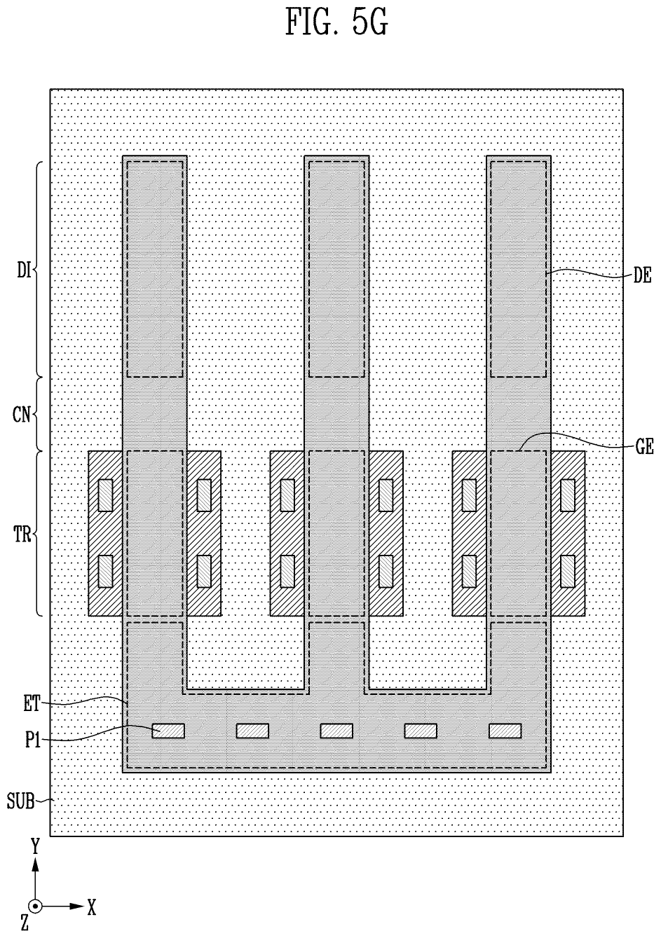

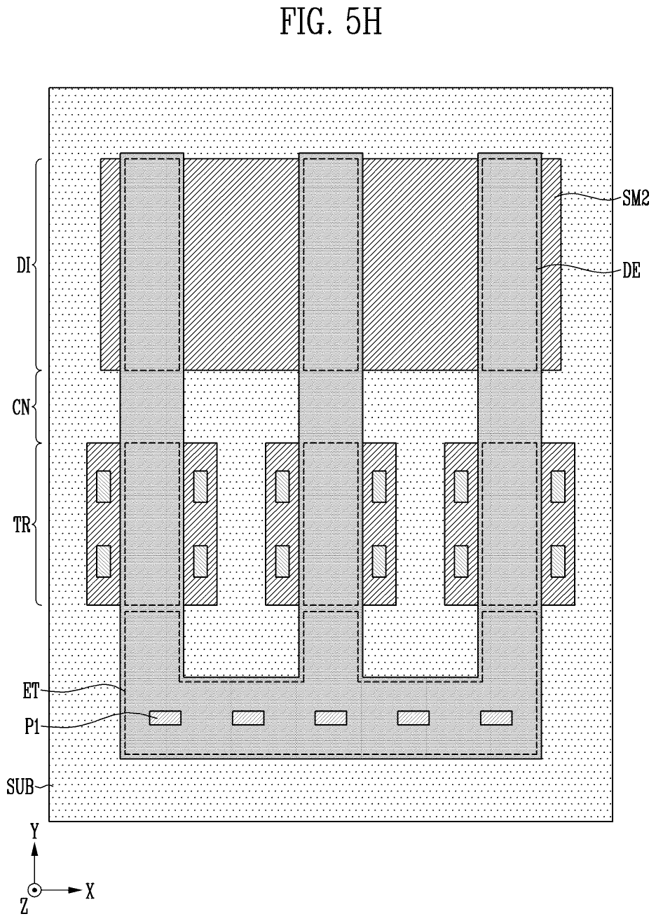

Referring to FIGS. 3A, 3D, and 3E, the transistor TR and the diode DI may be spaced apart from each other. For instance, the source region SR, drain region DR, and gate insulating layer GI of the transistor TR may be disposed to be spaced apart from the first semiconductor region SM1 and second semiconductor region SM2 of the diode DI. In an embodiment, the transistor TR and the diode DI may be arranged side by side along one direction. For instance, the transistor TR may be located in the Y direction from the diode DI. In addition, the transistor TR and the diode DI may be arranged in various ways. Various arrangements of the transistor TR and the diode DI are described later with reference to FIGS. 5A to 5H.

Referring to FIGS. 3A, 3D, and 3E, the gate electrode GE of the transistor TR and the diode electrode DE of the diode DI may be integrally formed. For instance, the gate electrode GE and the diode electrode DE may be simultaneously formed. Further, the gate electrode GE and the diode electrode DE may contain the same material. The gate electrode GE and the diode electrode DE may have the same thickness.

The diode electrode DE may extend from the gate electrode GE. The gate electrode GE and the diode electrode DE may extend from each other to have a stepped shape. For instance, the gate electrode GE and the diode electrode DE may have a step due to the gate insulating layer GI. The gate electrode GE may be located at a higher level (e.g., in the Z direction) than the diode electrode DE.

Because the gate electrode GE and the diode electrode DE are integrally formed, a connector CN connecting the gate electrode GE and the diode electrode DE may be formed. For example, referring to FIGS. 3D and 3E, the connector CN may be interposed between the gate electrode GE and the diode electrode DE. The gate electrode GE may be located in the Y direction from the connector CN, while the diode electrode DE may be located in a direction opposite to the Y direction from the connector CN.

The connector CN may electrically connect the gate electrode GE and the diode electrode DE. The gate electrode GE, the diode electrode DE, and the connector CN may be integrally formed. The gate electrode GE, the diode electrode DE, and the connector CN may be simultaneously formed. The gate electrode GE, the diode electrode DE, and the connector CN may contain the same material (e.g., metal). The gate electrode GE may be electrically connected to the diode electrode DE through the connector CN.

In the present disclosure, the gate electrode GE, the diode electrode DE, and the connector CN are divided for the convenience of description. However, the gate electrode, the diode electrode, and the connector might not be physically separated (e.g., seamless) and a boundary between them might be absent. Although FIGS. 3A to 3E show that the connector CN is located between the gate electrode GE and the diode electrode DE, this is merely illustrative and does not limit the scope of the present disclosure. For instance, as described later with reference to FIG. 5E, as long as the connector CN electrically connects the gate electrode GE and the diode electrode DE, the location of the connector CN is not limited to a location between the gate electrode GE and the diode electrode DE.

Referring to FIGS. 3B to 3D, an insulating layer IL may be located on the substrate SUB. The insulating layer IL is not shown in FIGS. 3A and 3E. The insulating layer IL may cover the transistor TR and the diode DI. The insulating layer IL may include an insulating material (e.g., oxide layer).

Referring to FIGS. 3A to 3D, the peripheral circuit structure PC may include an interconnection structure. The interconnection structure may be formed inside the insulating layer IL. The interconnection structure may include a conductive material (e.g., metal such as tungsten (W), copper (Cu), or molybdenum (Mo)). The interconnection structure may include a first plug P1, a first line L1, a second plug P2, transistor plugs PT, and transistor lines LT.

The first plug P1 may be electrically connected to the gate electrode GE and the diode electrode DE. Further, the first plug P1 might not overlap the transistor TR. For example, referring to FIGS. 3A, 3C, 3D, and 3E, the first plug P1 may contact the diode electrode DE. The first plug P1 may contact the upper surface of the diode electrode DE. The first plug P1 may be electrically connected to the gate electrode GE through the diode electrode DE. The gate electrode GE may be electrically connected to the first plug P1 through the connector CN and the diode electrode DE. The first plug P1 may have a square pillar shape, a shape extending in the Y direction (e.g., a line shape), or a cylindrical shape. In addition, the first plug P1 may have various shapes.

The first line L1 may be electrically connected to the first plug P1. The first line L1 may contact the upper surface of the first plug P1. The first line L1 may have the shape of a line extending in one direction (e.g., Y direction).

The second plug P2 may be electrically connected to the first line L1. The second plug P2 may contact the upper surface of the first line L1. The location of the second plug P2 shown in FIGS. 3A, 3B, and 3D is merely illustrative and does not limit the scope of the present disclosure. For instance, the second plug P2 might or might not overlap the transistor TR.

Each of transistor plugs PT may contact the source region SR or drain region DR of the transistor TR. The transistor plugs PT may each have a longer length in the Z direction than the first plug P1. The transistor lines LT may be electrically connected to the transistor plugs PT, respectively. The transistor lines LT may contact the upper surfaces of the transistor plugs PT, respectively. The transistor lines LT may be located at the same level as the first line L1. Although not shown in the drawing, plugs electrically connected to the transistor lines LT, respectively, may be further formed on the transistor lines LT.

In the present disclosure, the diode DI may be an anti-arcing diode. Charges (e.g., charges contained in an etchant) that are injected while the first line L1 or the second plug P2 is formed may be transferred through the first plug P1 to the diode DI. If, unlike the present disclosure, the first plug P1 contacts the gate electrode GE of the transistor TR, the charges may reach the gate insulating layer GI and then damage the gate insulating layer GI. However, in the present disclosure, the first plug P1 does not directly contact the gate electrode GE of the transistor TR, so it is possible to reduce the risk of the charge reaching the gate insulating layer GI and damaging the gate insulating layer GI.

In the present disclosure, the operation of the transistor TR may be controlled through the first plug P1. Because the diode electrode DE of the diode DI and the gate electrode GE of the transistor TR are electrically connected to each other, the transistor TR may be controlled through the first plug P1. Because the gate electrode GE is electrically connected to the first plug P1 through the diode electrode DE, current applied to the gate electrode GE may be transmitted through the first plug P1.

Further, the gate electrode GE of the transistor TR and the diode electrode DE of the diode DI are integrated with each other, so it is possible to reduce the volume of the peripheral circuit structure PC compared to a case where the diode DI is disposed separately from the transistor TR.

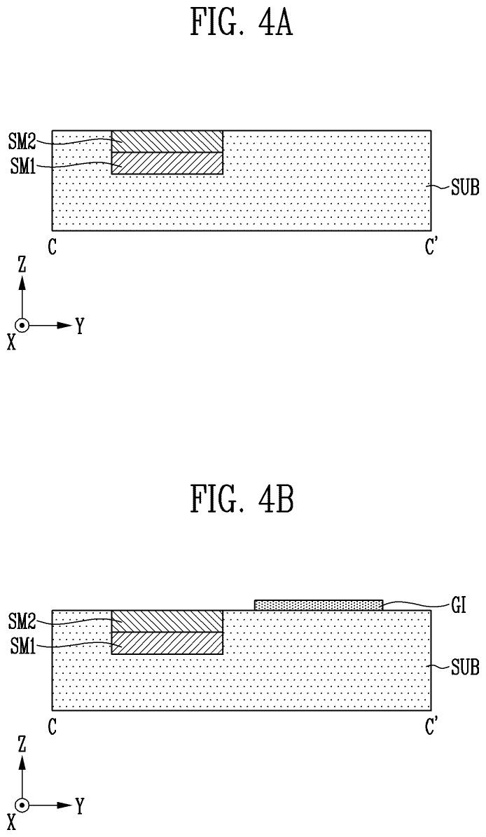

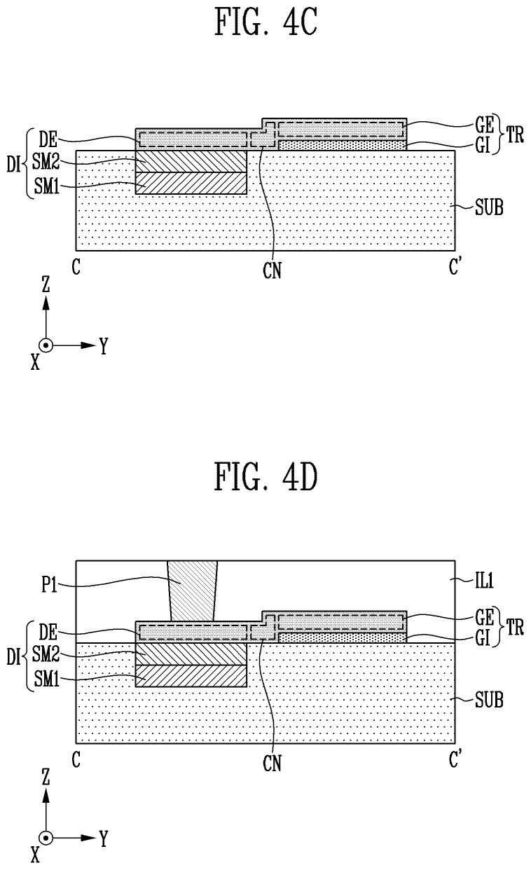

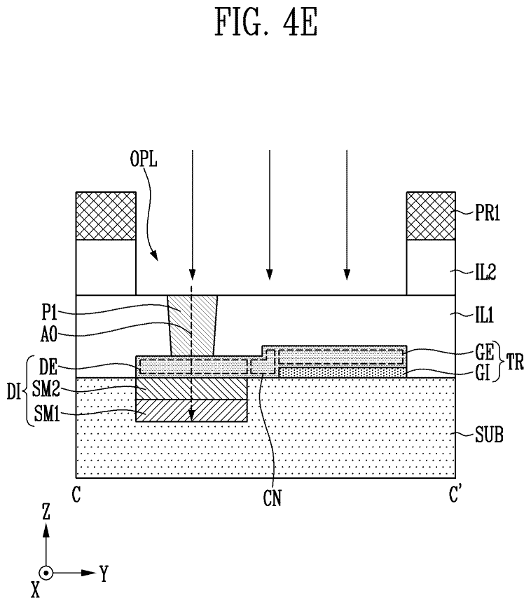

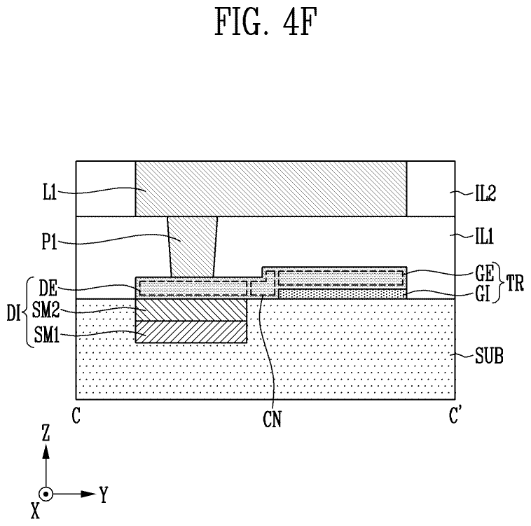

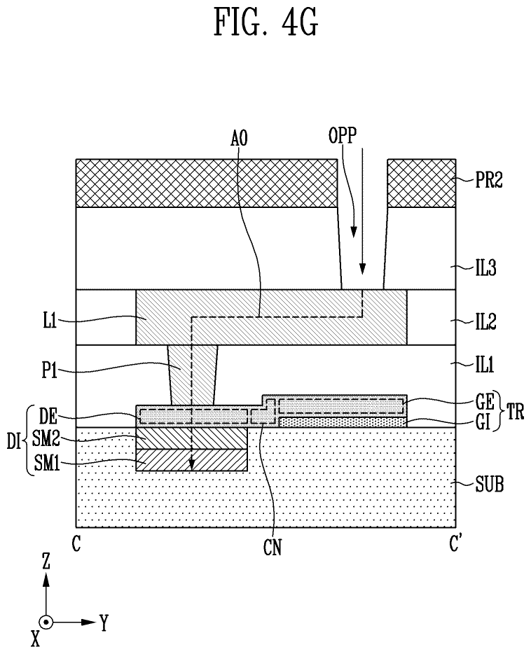

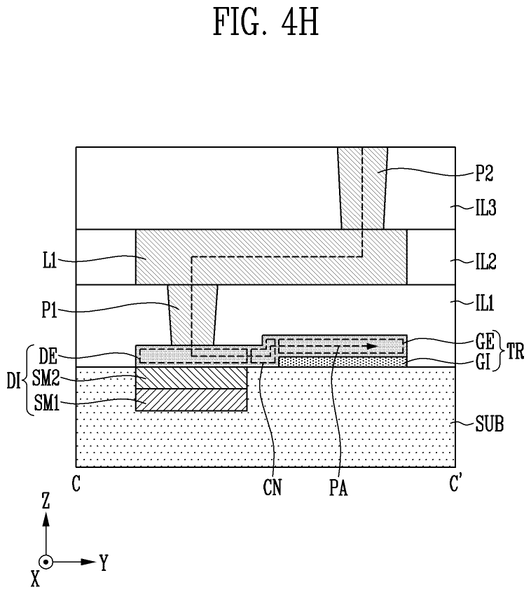

FIGS. 4A to 4H are diagrams illustrating a method of manufacturing a peripheral circuit structure according to an embodiment of the present disclosure. FIGS. 4A to 4H are sectional views taken along line C-C′ of FIG. 3A.

Referring to FIG. 4A, a first semiconductor region SM1 and a second semiconductor region SM2 may be formed in a substrate SUB. The first semiconductor region SM1 may be formed by injecting a first type (e.g., N type) of impurities into the substrate SUB. The second semiconductor region SM2 may be formed by injecting a second type (e.g., P type) of impurities into an upper portion of the first semiconductor region SM1.

Although not shown in the drawing, a source region SR and a drain region DR may be formed in the substrate SUB. The source region SR and the drain region DR may be formed by injecting the impurities (e.g., N type or P type of impurities) into the substrate SUB. The source region SR and the drain region DR may be formed before the first and second semiconductor regions SM1 and SM2 are formed, after the first and second semiconductor regions SM1 and SM2 are formed, or at the same time as the first and second semiconductor regions SM1 and SM2 are formed.

Referring to FIG. 4B, a gate insulating layer GI may be formed on the substrate SUB. The gate insulating layer GI may be located between the source region SR and the drain region DR. For instance, the gate insulating layer GI might or might not overlap a portion of the source region SR and a portion of the drain region DR.

Referring to FIG. 4C, a gate electrode GE and a diode electrode DE may be formed above and on the substrate SUB, respectively. The gate electrode GE may be formed on the gate insulating layer GI. The gate electrode GE, the gate insulating layer GI, the source region SR, and the drain region DR may form a transistor TR. The diode electrode DE may be formed on the second semiconductor region SM2. The diode electrode DE, the second semiconductor region SM2, and the first semiconductor region SM1 may form a diode DI.

The diode electrode DE may extend from the gate electrode GE. A connector CN may be formed between the gate electrode GE and the diode electrode DE. The gate electrode GE, the diode electrode DE, and the connector CN may be integrally formed. The gate electrode GE may contact the upper surface of the gate insulating layer GI, and the connector CN may contact a side of the gate insulating layer GI. The gate electrode GE and the diode electrode DE may form a stepped structure having a step due to the gate insulating layer GI elevating the gate electrode GE relative to the diode electrode DE.

The gate electrode GE and the diode electrode DE may be simultaneously formed. For instance, a conductive material may be formed on the entire structure of FIG. 4B. The conductive material may cover the gate insulating layer GI and the second semiconductor region SM2. Subsequently, a portion of the conductive material may be removed. As a portion of the conductive material is etched, the gate electrode GE and the diode electrode DE extending from each other may be formed.

Referring to FIG. 4D, a first insulating layer IL1 and a first plug P1 may be formed on the substrate SUB. The first insulating layer IL1 may cover the transistor TR and the diode DI. The first plug P1 may penetrate the first insulating layer IL1. The first plug P1 may be electrically connected to the diode electrode DE and the gate electrode GE. The first plug P1 might not overlap the transistor TR. For instance, the first plug P1 may contact the diode electrode DE. A portion of the upper surface of the diode electrode DE may be exposed by removing a portion of the first insulating layer IL1. Subsequently, the first plug P1 may be filled in a space from where the first insulating layer IL1 was removed.

Referring to FIG. 4E, a second insulating layer IL2 may be formed on the first insulating layer IL1. Subsequently, a first photoresist pattern PR1 may be formed on the second insulating layer IL2. For instance, a photoresist covering the second insulating layer IL2 may be formed. The photoresist may contain a material whose chemical properties change with light. A first photoresist pattern PR1 including an opening may be formed through a process of exposing and developing the photoresist, that is, a process of patterning the photoresist. The first photoresist pattern PR1 may expose a portion of the second insulating layer IL2.

Subsequently, the second insulating layer IL2 may be etched according to the first photoresist pattern PR1. The second insulating layer IL2 may be etched by an etchant (e.g., plasma) supplied on the first photoresist pattern PR1. A portion of the second insulating layer IL2 may be removed to form a first opening OPL. The first opening OPL may expose the upper surface of the first plug P1.

While the first opening OPL is being formed, charge contained in the etchant used in an etching process may be transferred to the first plug P1. The charge may be transferred to the diode DI along arrow A0. That is, through the diode DI used as the anti-arcing diode. This may reduce or prevent defects resulting from the charge reaching the gate insulating layer GI of the transistor TR and damaging the gate insulating layer GI.

Referring to FIG. 4F, the first photoresist pattern PR1 may be removed from the second insulating layer IL2. Subsequently, a first line L1 may be formed in the first opening OPL. The first line L1 may contact the upper surface of the first plug P1. For instance, a conductive material may be formed on the second insulating layer IL2 and in the first opening OPL, and the first line L1 may be formed through a planarization process of the conductive material.

Referring to FIG. 4G, a third insulating layer IL3 may be formed on the second insulating layer IL2. Subsequently, a second photoresist pattern PR2 may be formed on the third insulating layer IL3.

The third insulating layer IL3 may be etched according to the second photoresist pattern PR2. The third insulating layer IL3 may be etched by an etchant supplied on the second photoresist pattern PR2. A portion of the third insulating layer IL3 may be removed to form a second opening OPP. The second opening OPP may expose a portion of the upper surface of the first line L1.

While the second opening OPP is formed, charge contained in the etchant used in the etching process may be transferred to the first line L1 and the first plug P1. The charge may be transferred as indicated by arrow A0 to the diode DI. That is, through the diode DI used as the anti-arcing diode. This may reduce or prevent defects resulting from the charge reaching the gate insulating layer GI of the transistor TR and damaging the gate insulating layer GI.

Referring to FIG. 4H, the second photoresist pattern PR2 may be removed from the third insulating layer IL3. Subsequently, a second plug P2 may be formed in the second opening OPP. The second plug P2 may contact the upper surface of the first line L1.

After the manufacturing process of the semiconductor device 100 according to the present disclosure is completed, the operation of the transistor TR may be controlled through the first plug P1. Because the diode electrode DE of the diode DI and the gate electrode GE of the transistor TR are electrically connected to each other, current applied to the gate electrode GE of the transistor TR may be transmitted through a current path PA. For instance, the current applied to the gate electrode GE may be transmitted through the second plug P2, the first line L1, the first plug P1, the diode electrode DE, and the connector CN.

In the present disclosure, the first insulating layer IL1, the second insulating layer IL2, and the third insulating layer IL3 may be understood as being included in the insulating layer IL of FIGS. 3B to 3D. The first insulating layer IL1, the second insulating layer IL2, and the third insulating layer IL3 are divided for the convenience of description, and their boundaries might not be clearly observed in a final structure.

FIGS. 5A to 5H are diagrams illustrating configurations of a peripheral circuit structure according to other embodiments of the present disclosure.

FIGS. 3A to 3E and FIGS. 4A to 4H illustrate an embodiment of the present disclosure, that is, an embodiment where one transistor TR and one diode DI are connected through the diode electrode DE and the gate electrode GE, and the first plug P1 contacts the diode electrode DE. FIGS. 5A to 5H illustrate additional embodiments included in the present disclosure. FIGS. 5A to 5H are plan views of the peripheral circuit structure PC as seen from the Z direction. Among the configurations shown in FIGS. 5A to 5H, the configuration described in relation to FIGS. 3A to 3E and FIGS. 4A to 4H may be briefly described or omitted.

Referring to FIG. 5A, at least two transistors (e.g., first to third transistors TR1 to TR3) may be arranged in one direction (e.g., Y direction) from the diode DI. The diode DI, the first transistor TR1, the second transistor TR2, and the third transistor TR3 may be arranged in one direction (e.g., Y direction).

The diode DI may include a diode electrode DE. Although not shown in the drawing, the diode DI may further include first and second semiconductor regions (e.g., SM1 and SM2 in FIG. 3A) under the diode electrode DE. In FIGS. 5A to 5H, among electrode material layers (e.g., the diode electrode, the gate electrode, the connector, etc.) that are integrally formed, a portion overlapping the first and second semiconductor regions may be shown to correspond to the diode electrode DE.

The first transistor TR1 may include a first gate electrode GE1, a first source region SR1, and a first drain region DR1. The second transistor TR2 may include a second gate electrode GE2, a second source region SR2, and a second drain region DR2. The third transistor TR3 may include a third gate electrode GE3, a third source region SR3, and a third drain region DR3. Although not shown in the drawing, the first to third transistors TR1 to TR3 may further include gate insulating layers (e.g., GI in FIG. 3A). The transistor plugs PT may be disposed on the first source region SR1, the first drain region DR1, the second source region SR2, the second drain region DR2, the third source region SR3, and the third drain region DR3.

The diode electrode DE may be electrically connected to the first gate electrode GE1, the second gate electrode GE2, and the third gate electrode GE3. The third gate electrode GE3 may be electrically connected to the diode electrode DE through the second gate electrode GE2 and the first gate electrode GE1. The diode electrode DE, the first gate electrode be integrally formed. The diode electrode DE, the first gate electrode GE1, the second gate electrode GE2, and the third gate electrode GE3 may extend from each other. That is, at least two gate electrodes (e.g., GE1 to GE3) may be electrically connected to any one diode electrode DE.

The connectors CN may be located between the diode electrode DE, the first gate electrode GE1, the second gate electrode GE2, and the third gate electrode GE3. The connectors CN may be located between the diode electrode DE and the first gate electrode GE1, between the first gate electrode GE1 and the second gate electrode GE2, and between the second gate electrode GE2 and the third gate electrode GE3. The diode electrode DE, the first gate electrode GE1, the second gate electrode GE2, the third gate electrode GE3, and the connectors CN may be integrally formed.

The first plug P1 may be electrically connected to the diode electrode DE, the first gate electrode GE1, the second gate electrode GE2, and the third gate electrode GE3. Further, the first plug P1 might not overlap the first to third transistors TR1 to TR3. Referring to FIG. 5A, the first plug P1 may contact the diode electrode DE. The first to third gate electrodes GE1 to GE3 may be electrically connected to the first plug P1 through the diode electrode DE.

With respect to FIG. 5B, the description of the configuration described in relation to FIG. 5A may be omitted. Referring to FIG. 5B, at least one transistor (e.g., first and second transistors TR1 and TR2) may be disposed on both sides of the diode DI (e.g., in the Y direction and in the direction opposite to the Y direction). For instance, the first transistor TR1 may be located in the direction opposite to the Y direction from the diode DI, while the second transistor TR2 may be located in the Y direction from the diode DI.

The diode electrode DE may be electrically connected to the first gate electrode GE1 and the second gate electrode GE2. The diode electrode DE, the first gate electrode GE1, and the second gate electrode GE2 may be integrally formed. The first gate electrode GE1, the diode electrode DE, and the second gate electrode GE2 may extend from each other. That is, at least two gate electrodes (e.g., GE1 and GE2) may be electrically connected to any one diode electrode DE.

The connectors CN may be located between the diode electrode DE, the first gate electrode GE1, and the second gate electrode GE2. The connectors CN may be located between the diode electrode DE and the first gate electrode GE1, and between the diode electrode DE and the second gate electrode GE2. The second gate electrode GE2 and the first gate electrode GE1 may be electrically connected to the diode electrode DE through the connectors CN. The diode electrode DE, the first gate electrode GE1, the second gate electrode GE2, and the connectors CN may be integrally formed.

The first plug P1 may be electrically connected to the diode electrode DE, the first gate electrode GE1, and the second gate electrode GE2. Further, the first plug P1 might not overlap the first and second transistors TR1 and TR2. Referring to FIG. 5B, the first plug P1 may contact the diode electrode DE. The first and second gate electrodes GE1 and GE2 may be electrically connected to the first plug P1 through the diode electrode DE.

With respect to FIG. 5C, the description of the configuration described in relation to FIGS. 5A and 5B may be omitted. Referring to FIG. 5C, at least two transistors (e.g., first to third transistors TR1 to TR3) may be arranged in one direction (e.g., Y direction) from the diode DI. The first transistor TR1, the second transistor TR2, and the third transistor TR3 may be located in the Y direction from the diode DI. Further, the first transistor TR1, the second transistor TR2, and the third transistor TR3 may be arranged along the X direction.

At least one transistor plug PT may be disposed on the first source region SR1, the first drain region DR1, the second source region SR2, the second drain region DR2, the third source region SR3, and the third drain region DR3, respectively. For instance, two transistor plugs PT may be connected to the first source region SR1, the first drain region DR1, the second source region SR2, the second drain region DR2, the third source region SR3, and the third drain region DR3, respectively.

The diode electrode DE may be electrically connected to the first gate electrode GE1, the second gate electrode GE2, and the third gate electrode GE3. The diode electrode DE, the first gate electrode GE1, the second gate electrode GE2, and the third gate electrode GE3 may be integrally formed. Each of the first gate electrode GE1, the second gate electrode GE2, and the third gate electrode GE3 may extend from the diode electrode DE. That is, at least two gate electrodes (e.g., GE1 to GE3) may be electrically connected to any one diode electrode DE.

The connectors CN may be located between the diode electrode DE, the first gate electrode GE1, the second gate electrode GE2, and the third gate electrode GE3. The connectors CN may be located between the diode electrode DE and the first gate electrode GE1, between the diode electrode DE and the second gate electrode GE2, and between the diode electrode DE and the third gate electrode GE3. The first gate electrode GE1, the second gate electrode GE2, and the third gate electrode GE3 may be electrically connected through the connectors CN to the diode electrode DE, respectively. The diode electrode DE, the first gate electrode GE1, the second gate electrode GE2, the third gate electrode GE3, and the connectors CN may be integrally formed.

The first plugs P1 may be electrically connected to the diode electrode DE, the first gate electrode GE1, the second gate electrode GE2, and the third gate electrode GE3. Further, the first plugs P1 might not overlap the first to third transistors TR1 to TR3. Referring to FIG. 5C, the first plugs P1 may contact the diode electrode DE. At least two (e.g., five) first plugs P1 may be formed on the diode electrode DE. The first to third gate electrodes GE1 to GE3 may be electrically connected to the first plug P1 through the diode electrode DE.

With respect to FIG. 5D, the description of the configuration described in relation to FIGS. 5A to 5C may be omitted. Referring to FIG. 5D, the connector CN may be located between the gate electrode GE of the transistor TR and the diode electrode DE of the diode DI.

The first plug P1 might not overlap the transistor TR or the diode DI. Referring to FIG. 5D, the first plug P1 may contact the connector CN. The diode electrode DE may be connected to the first plug P1 through the connector CN. Thus, during the manufacturing process of the semiconductor device 100, the charge (e.g., charge contained in the etchant) transferred to the first plug P1 may be transmitted to the diode DI. Further, the gate electrode GE may be connected to the first plug P1 through the connector CN. Therefore, during the operation of the semiconductor device 100, current may be applied to the gate electrode GE through the first plug P1.

With respect to FIG. 5E, the description of the configuration described in relation to FIGS. 5A to 5D may be omitted. Referring to FIG. 5E, at least one transistor (e.g., first and second transistors TR1 and TR2) may be disposed, respectively, on both sides (e.g., the X direction and the direction opposite to the X direction) of the diode DI. For instance, the first transistor TR1 may be located in the direction opposite to the X direction from the diode DI, while the second transistor TR2 may be located in the X direction from the diode DI. The first transistor TR1, the diode DI, and the second transistor TR2 may be arranged along the X direction.

The connector CN may electrically connect the diode electrode DE, the first gate electrode GE1, and the second gate electrode GE2. The connector CN may be located in the direction opposite to the Y direction from each of the diode electrode DE, the first gate electrode GE1, and the second gate electrode GE2. For instance, the connector CN may have an E-shaped plane. Comparing FIG. 5E with FIG. 5D, the connector CN may connect the diode DI and the transistor TR1 or TR2 even if it is not located between the diode DI and the transistor TR1 or TR2. Each of the second gate electrode GE2 and the first gate electrode GE1 may be electrically connected to the diode electrode DE through the connector CN. The diode electrode DE, the first gate electrode GE1, the second gate electrode GE2, and the connector CN may be integrally formed.

The first plugs P1 might not overlap the transistor TR and the diode DI. Referring to FIG. 5E, the first plugs P1 may contact the connector CN. At least two first plugs P1 may be formed on the connector CN. The diode electrode DE may be connected to the first plugs P1 through the connector CN. Further, the gate electrode GE may be connected to the first plugs P1 through the connector CN.

With respect to FIG. 5F, the description of the configuration described in relation to FIGS. 5A to 5E may be omitted. Referring to FIG. 5F, an extender ET may be located in the Y direction from the gate electrode GE.

The extender ET may be electrically connected to the gate electrode GE and the diode electrode DE. The extender ET may extend from the gate electrode GE in a direction (e.g., the Y direction) opposite to the direction (e.g., the direction opposite to the Y direction) in which the diode electrode DE is disposed. The extender ET, the gate electrode GE, the connector CN, and the diode electrode DE may be integrally formed. The diode electrode DE may be electrically connected to the extender ET through the connector CN and the gate electrode GE.

The first plug P1 might not overlap the transistor TR and the diode DI. Referring to FIG. 5F, the first plug P1 may contact the extender ET. The diode electrode DE may be connected to the first plug P1 through the connector CN, the gate electrode GE, and the extender ET. Further, the gate electrode GE may be connected to the first plug P1 through the extender ET.

With respect to FIG. 5G, the description of the configuration described in relation to FIGS. 5A to 5F may be omitted. Referring to FIG. 5G, the diodes DI may be arranged along the X direction. Further, the transistors TR may be arranged along the X direction. Each of the transistors TR may be disposed in one direction (e.g., the direction opposite to the Y direction) from each of the diodes DI. The diode electrodes DE may be electrically connected to the gate electrodes GE. For instance, each of the diode electrodes DE and each of the gate electrodes GE may be connected in a one-on-one manner. The connector CN may be disposed between each of the diode electrodes DE and each of the gate electrodes GE.

The extender ET may be located in the direction opposite to the Y direction from the gate electrodes GE. The extender ET may extend in the direction (e.g., the direction opposite to the Y direction) opposite to the direction (e.g., Y direction) in which the diode electrodes DE are disposed from the gate electrodes GE, respectively. The extender ET may be electrically connected to the gate electrodes GE and the diode electrodes DE.

Further, the extender ET may connect at least two gate electrodes GE to each other. For instance, the extender ET may have an E-shaped plane. That is, at least two diode electrodes DE and at least two gate electrodes GE may be electrically connected to each other via the extender ET. The extender ET, the gate electrodes GE, the connectors CN, and the diode electrodes DE may be integrally formed. The diode electrodes DE may be electrically connected to the extender ET through the connectors CN and the gate electrodes GE.

The first plugs P1 might not overlap the transistors TR and the diodes DI. Referring to FIG. 5G, the first plugs P1 may contact the extender ET. Each of the diode electrodes DE may be connected to the first plug P1 through each of the connectors CN, each of the gate electrodes GE, and the extender ET. Further, each gate electrode GE may be connected to the first plug P1 through the extender ET.

With respect to FIG. 5H, the description of the configuration described in relation to FIGS. 5A to 5G may be omitted. Referring to FIG. 5H, the diode electrodes DE may overlap a portion of the second semiconductor region SM2. A portion of the second semiconductor region SM might not overlap the diode electrodes DE. Although not shown in the drawing, the first semiconductor region SM1 is located under the second semiconductor region SM2, so a portion of the first semiconductor region SM1 may also not overlap the diode electrodes DE. That is, the first and second semiconductor regions SM1 and SM2 included in the diodes DI may be integrally formed without being separated from each other.

Although it is shown in FIG. 5H that three diode electrodes DE are formed on one second semiconductor region SM2, at least one diode electrode DE may overlap a portion of one second semiconductor region SM2. That is, although it is shown in FIGS. 5A to 5G that the entire second semiconductor region SM2 overlaps the diode electrode DE, only a portion of the second semiconductor region SM2 might overlap the diode electrode DE, and the other portion might not overlap the diode electrode DE.

The embodiments shown in FIGS. 5A to 5H are merely illustrative and not exhaustive. In addition to the embodiments shown in FIGS. 5A to 5H, various other embodiments are possible in which the first plug P1 does not overlap the transistor TR and is electrically connected to the diode electrode DE and the gate electrode GE.

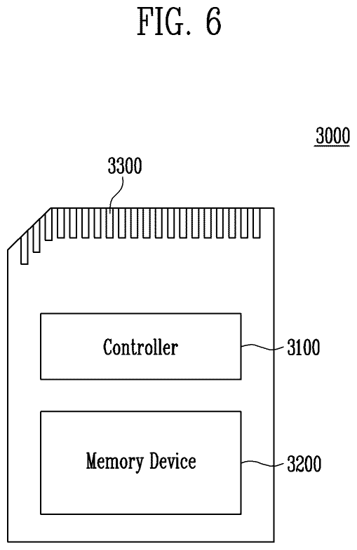

FIG. 6 is a diagram illustrating a memory card system to which a semiconductor device according to an embodiment of the present disclosure is applied.

Referring to FIG. 6, a memory card system 3000 may include a controller 3100, a memory device 3200, and a connector 3300.

The controller 3100 may be coupled to the memory device 3200. The controller 3100 may access the memory device 3200. For example, the controller 3100 may control a program operation, a read operation, or an erase operation of the memory device 3200, or may control a background operation of the memory device 3200. The controller 3100 may provide an interface between the memory device 3200 and a host. The controller 3100 may run firmware for controlling the memory device 3200. In an example, the controller 3100 may include components, such as random-access memory (RAM), a processor, a host interface, a memory interface, and an error corrector.

The controller 3100 may communicate with an external device through the connector 3300. The controller 3100 may communicate with an external device (e.g., a host) based on a specific communication standard. For example, the controller 3100 may communicate with the external device through at least one of various communication standards such as universal serial bus (USB), multimedia card (MMC), embedded MMC (eMMC), peripheral component interconnection (PCI), PCI-express (PCI-E), advanced technology attachment (ATA) protocol, serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe). For example, the connector 3300 may be defined by at least one of the above-described various communication standards.

The memory device 3200 may include a plurality of memory cells. Further, the memory device 3200 may be configured in the same manner as the semiconductor device 100 illustrated in FIG. 1.

The controller 3100 and the memory device 3200 may be integrated into a single semiconductor device to form a memory card. For example, the controller 3100 and the memory device 3200 may be integrated into a single semiconductor device, and may then form a memory card such as a personal computer memory card international association (PCMCIA) card, a compact flash card (CF), a smart media card (SM or SMC), a memory stick, a multimedia card (MMC, RS-MMC, MMCmicro or eMMC), an SD card (SD, miniSD, microSD, or SDHC), or a universal flash storage (UFS).

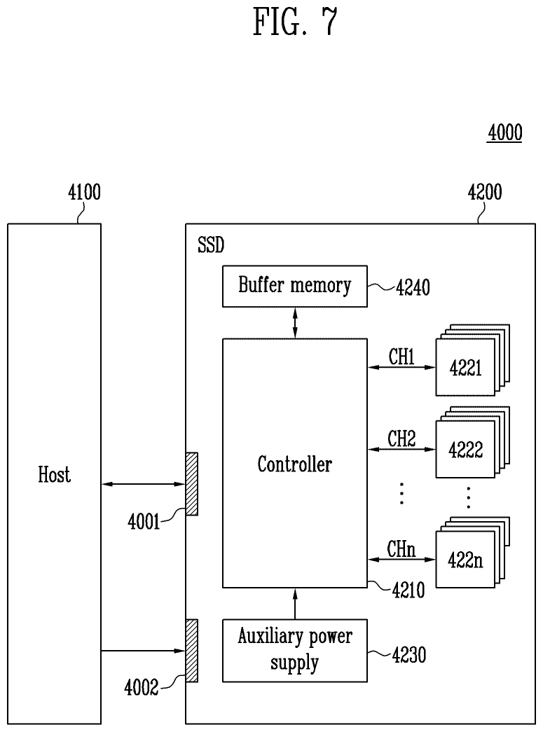

FIG. 7 is a diagram illustrating a solid-state drive (SSD) system to which a semiconductor device according to the present disclosure is applied.

Referring to FIG. 7, an SSD system 4000 may include a host 4100 and an SSD 4200. The SSD 4200 may exchange signals with the host 4100 through a signal connector 4001. The SSD 4200 may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to signals received from the host 4100. For example, the received signals may be signals based on the interfaces of the host 4100 and the SSD 4200. For example, the signals may be defined by at least one of various interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe).

Each of the plurality of memory devices 4221 to 422n may include a plurality of memory cells configured to store data. Each of the memory devices 4221 to 422n may be configured in the same manner as the semiconductor device 100 illustrated in FIG. 1. The plurality of memory devices 4221 to 422n may communicate with the controller 4210 through channels CH1 to CHn, respectively.

The auxiliary power supply 4230 may be coupled to the host 4100 through the power connector 4002. The auxiliary power supply 4230 may be supplied with a supply voltage from the host 4100 and may be charged. The auxiliary power supply 4230 may provide the supply voltage of the SSD 4200 when the supply of power from the host 4100 is not smoothly performed. For example, the auxiliary power supply 4230 may be located inside the SSD 4200 or located outside the SSD 4200. For example, the auxiliary power supply 4230 may be located on a main board and may provide auxiliary power to the SSD 4200.

The buffer memory 4240 may function as buffer memory of the SSD 4200. For example, the buffer memory 4240 may temporarily store data received from the host 4100 or data received from the plurality of memory devices 4221 to 422n, or may temporarily store metadata (e.g., mapping tables) of the memory devices 4221 to 422n. The buffer memory 4240 may include volatile memory, such as dynamic random-access memory (DRAM), synchronous DRAM (SDRAM), double data rate (DDR) SDRAM, and low power DDR (LPDDR) SDRAM, or nonvolatile memory, such as ferroelectric RAM (FRAM), resistive RAM (ReRAM), spin transfer torque magnetic RAM (STT-MRAM), and phase-change RAM (PRAM).

According to some embodiments of the present disclosure, damage to a peripheral circuit structure can be reduced and the size of the peripheral circuit structure can be reduced by changing the configuration of the peripheral circuit structure.

What is claimed is:

1. A semiconductor device, comprising:
a transistor including a gate insulating layer and a gate electrode stacked on a substrate;
a diode including a diode electrode, wherein the diode electrode is on the substrate, extends from the gate electrode, and is electrically connected to the gate electrode; and
a first plug physically and electrically connected to the diode electrode.

2. The semiconductor device according to claim 1, wherein the gate electrode and the diode electrode are integrally formed.

3. The semiconductor device according to claim 1, wherein the first plug does not overlap the transistor.

4. The semiconductor device according to claim 3, wherein the first plug is electrically connected to the gate electrode through the diode electrode.

5. The semiconductor device according to claim 1, further comprising:
a connector disposed between the gate electrode and the diode electrode, the connector electrically connecting the gate electrode to the diode electrode.

6. The semiconductor device according to claim 5, wherein the first plug contacts the connector.

7. The semiconductor device according to claim 6, wherein the first plug does not overlap the diode.

8. The semiconductor device according to claim 1, further comprising:
an extender electrically connected to the gate electrode and the diode electrode, the extender extending from the gate electrode in a direction opposite to a direction in which the diode electrode is disposed from the gate electrode.

9. The semiconductor device according to claim 8, wherein the first plug contacts the extender.

10. The semiconductor device according to claim 1, wherein the gate electrode and the diode electrode extend from each other to have a stepped shape.

11. The semiconductor device according to claim 1, wherein the insulating layer is disposed between the substrate and the gate electrode, and the gate electrode extends farther above the substrate than the diode electrode.

12. The semiconductor device according to claim 1, wherein the gate electrode and the diode electrode have the same thickness.

13. The semiconductor device according to claim 1, wherein the transistor further comprises a source region and a drain region that are formed in the substrate and are adjacent to opposite sides of the gate insulating layer.

14. The semiconductor device according to claim 1, wherein the diode further comprises:
a first semiconductor region formed in the substrate and including a first type of impurity; and
a second semiconductor region formed in the substrate, located between the first semiconductor region and the diode electrode, and including a second type of impurity different from the first type of impurity.

15. A method of manufacturing a semiconductor device, the method comprising:
forming a transistor including a gate insulating layer and a gate electrode stacked on a substrate; and
forming a diode including a diode electrode, the diode electrode formed on the substrate and extending from the gate electrode; and
forming a first plug that is physically connected to the diode electrode and electrically connected to both the gate electrode and the diode electrode, wherein the first plug is formed to not overlap the transistor.

16. The method according to claim 15, wherein forming the transistor comprises:
forming a source region and a drain region in the substrate;
forming the gate insulating layer on the substrate between the source region and the drain region; and
forming the gate electrode on the gate insulating layer.

17. The method according to claim 16, wherein forming the diode comprises:
forming a first semiconductor region by injecting a first type of impurity into the substrate;
forming a second semiconductor region by injecting a second type of impurity different from the first type of impurity into the substrate above the first semiconductor region; and
forming the diode electrode on the second semiconductor region.

18. The method according to claim 17, wherein forming the gate electrode and forming the diode electrode are performed simultaneously.

19. The method according to claim 17, wherein forming the gate electrode and forming the diode electrode comprise:
forming a conductive material covering the gate insulating layer and the second semiconductor region on the substrate; and
forming the gate electrode and the diode electrode extending from each other, by removing a portion of the conductive material.

20. The method according to claim 15, wherein forming the first plug comprises forming the first plug to contact the diode electrode.

21. The method according to claim 15, further comprising:
forming a first line contacting an upper surface of the first plug; and
forming a second plug contacting an upper surface of the first line.

22. The method according to claim 21, wherein forming the second plug comprises forming the second plug such that a charge used to form the second plug is transferred to the diode.
